(19) United States
(12) Patent Application Publication
(10) Pub. No.: US 2025/0001583 A1
(43) Pub. Date: Jan. 2, 2025

(54) SUBSTRATE TRANSFER APPARATUS

(71) Applicant: VM Inc., Icheon-si (KR)

(72) Inventors: Tae Jin Kwon, Anseong-si (KR); Woo Hyung Choi, Seongnam-si (KR); Sang Woo Lee, Suwon-si (KR)

(73) Assignee: VM Inc., Icheon-si (KR)

(21) Appl. No.: 18/660,167

(22) Filed: May 9, 2024

(30) Foreign Application Priority Data
Jun. 27, 2023 (KR) 10-2023-0082707

(51) Int. Cl. B25J 5/02; B25J 9/04; B25J 11/00; H01L 21/67; H01L 21/687

(52) U.S. Cl. CPC B25J 5/02; B25J 11/0095; H01L 21/67167; H01L 21/67196; H01L 21/68707; B25J 9/043

(57) ABSTRACT

A substrate transfer apparatus includes a moving plate, a load lock chamber disposed at one end of the moving plate, a plurality of processing chambers disposed in a longitudinal direction at opposite ends of the moving plate, and a first arm that is connected with the moving plate and that transfers a substrate between one processing chamber among the plurality of processing chambers and the load lock chamber. The moving plate provides a first path along which a first pivot axis of the first arm performs a circular motion on the moving plate.

### CROSS-REFERENCE TO RELATED APPLICATIONS

A claim for priority under 35 U.S.C. § 119 is made to Korean Patent Application No. 10-2023-0082707 filed on Jun. 27, 2023, in the Korean Intellectual Property Office, the entire contents of which are hereby incorporated by reference.

### BACKGROUND

Embodiments of the inventive concept described herein relate to a substrate transfer apparatus.

Throughput in equipment used for a semiconductor or display process refers to the number of wafers or substrates processed per unit time in a single process. In general, the throughput may be determined based on process time of a processing chamber, an intake/exhaust speed of a vacuum robot, cooling/heating time of a wafer, and the like, but in order to most simply improve the throughput in terms of an overall system, a method of increasing the number of apparatuses disposed in a limited space may be considered.

However, it is not economically easy to expand the area of a factory or secure a new large site. In addition, due to many factors, such as development restrictions according to laws, which make it impossible to expand a site in reality, many companies are actually experiencing difficulties in the stage of selecting sites for semiconductor factories.

### SUMMARY

Embodiments of the inventive concept provide a substrate transfer apparatus occupying a narrower area than a substrate transfer apparatus in the related art while processing a substrate with efficiency the same as or similar to efficiency in the related art or with efficiency improved when compared to the efficiency in the related art.

Specifically, embodiments of the inventive concept provide a substrate transfer apparatus for minimizing a lateral width of a moving plate by enabling an axis of a robot arm to perform a circular motion.

According to an exemplary embodiment, a substrate transfer apparatus includes a moving plate, a load lock chamber disposed at one end of the moving plate, a plurality of processing chambers disposed in a longitudinal direction at opposite ends of the moving plate, and a first arm that is connected with the moving plate and that transfers a substrate between one processing chamber among the plurality of processing chambers and the load lock chamber. The moving plate provides a first path along which a first pivot axis of the first arm performs a circular motion on the moving plate.

According to an embodiment, a position of the first pivot axis on the first path may be determined based on a position of the one processing chamber relative to the moving plate.

According to an embodiment, the first path may include at least one of an oval shape and an arc shape.

According to an embodiment, the substrate transfer apparatus may further include a second arm that is connected with the moving plate and that transfers the substrate between the one processing chamber among the plurality of processing chambers and the load lock chamber. The moving plate may provide the first path along which each of the first pivot axis of the first arm and a second pivot axis of the second arm performs a circular motion on the moving plate.

According to an embodiment, the substrate may be configured to pass through the second arm between the one processing chamber and the load lock chamber.

According to an embodiment, the substrate transfer apparatus may further include a third arm that is connected with the moving plate and that transfers the substrate between the one processing chamber among the plurality of processing chambers and the load lock chamber. The moving plate may provide a second path along which a third pivot axis of the third arm performs a circular motion on the moving plate.

According to an embodiment, the first path may include a rail.

According to an embodiment, the first path may include a plurality of links, and the first pivot axis may be disposed at one of the plurality of links to transfer the substrate from the one processing chamber.

According to an embodiment, when the substrate is transferred from a first unit to a second unit, the substrate may reach the second unit via a predetermined region based on a state of the second unit. Each of the first unit and the second unit may include one of the load lock chamber, the one processing chamber, and the first arm, and the first unit and the second unit may be configured differently from each other.

According to an embodiment, when the second unit is the first arm, the state may be associated with at least one of movement of the first arm, a position of the first arm, and whether the first arm accommodates another substrate.

According to an embodiment, when the second unit is the load lock chamber or the one processing chamber, the state may be associated with at least one of temperature, humidity, and pressure of the load lock chamber or the one processing chamber and whether another substrate is accommodated in the load lock chamber or the one processing chamber.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIGS. 1A and 1B are plan views illustrating different operations of a substrate transfer apparatus according to an embodiment of the inventive concept;

FIG. 2 is a plan view of a substrate transfer apparatus including a plurality of arms and a plurality of paths according to an embodiment of the inventive concept;

FIG. 3 is a plan view of a substrate transfer apparatus including a plurality of arms according to an embodiment of the inventive concept; and

FIGS. 4A and 4B are plan views of arm units including different members according to an embodiment of the inventive concept.

### DETAILED DESCRIPTION

Hereinafter, specific details for carrying out the inventive concept will be described in detail with reference to the accompanying drawings. However, detailed descriptions related to well-known functions or configurations will be omitted when they may make subject matters of the inventive concept unnecessarily obscure.

In the accompanying drawings, identical or corresponding components will be assigned with identical reference numerals. Furthermore, in the following description of embodiments, repetitive descriptions of the identical or corresponding components may be omitted. However, the omission of the descriptions of the components does not intend that the components are not included in certain embodiments.

Aspects, features, and advantages of the inventive concept will become apparent from the following description of embodiments given in conjunction with the accompanying drawings. However, the inventive concept is not limited to the embodiments disclosed herein and may be implemented in various different forms. Herein, the embodiments are provided to provide complete disclosure of the inventive concept and to provide thorough understanding of the inventive concept to those skilled in the art.

The terminology used herein will be described briefly, and the inventive concept will be described in detail. The terminology used herein is defined in consideration of the function of corresponding components used in the inventive concept and may be varied according to users, operator's intention, or practices. In addition, an arbitrary defined terminology may be used in a specific case and will be described in detail in a corresponding description paragraph. Therefore, the terminology used herein is for the purpose of describing particular embodiments only and is not intended to be limiting of the inventive concept.

The terms of a singular form may include plural forms unless otherwise specified. In addition, the terms of a plural form may include singular forms unless otherwise specified. In this specification, when a portion “includes” a component, it may mean that the portion does not exclude another component unless specifically described to the contrary, but may further include another component.

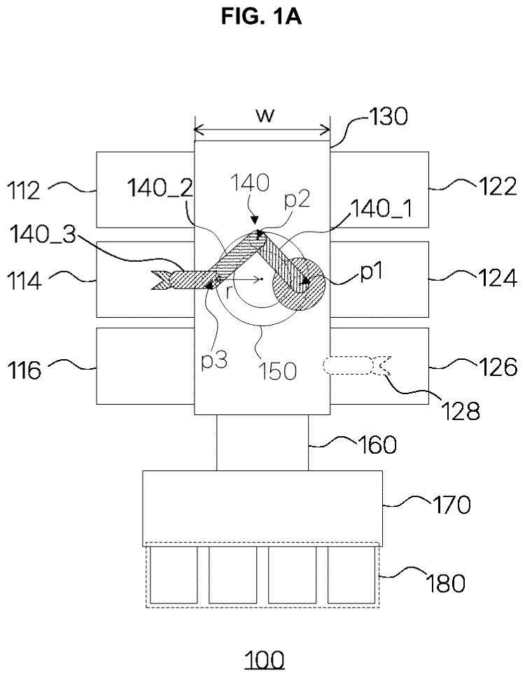

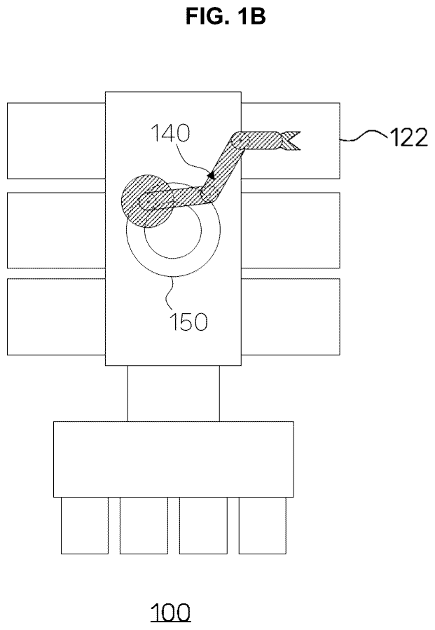

FIGS. 1A and 1B are plan views illustrating different operations of a substrate transfer apparatus 100 according to an embodiment of the inventive concept. As illustrated, the substrate transfer apparatus 100 may include at least one of a plurality of processing chambers 112 to 126, a moving plate 130, an arm 140, a load lock chamber 160, an equipment front end module (EFEM) 170, and a plurality of load port modules (LPMs) 180.

The arm 140 may transfer a substrate (e.g., a wafer) obtained from one LPM among the plurality of LPMs 180 to one target processing chamber (here, the second processing chamber 114) among the plurality of processing chambers 112 to 126 through the load lock chamber 160. In addition, the arm 140 may transfer the substrate processed in the target processing chamber among the plurality of processing chambers 112 to 126 to any one LPM through the load lock chamber 160. Meanwhile, a “target processing chamber” used herein may refer to a processing chamber into which a substrate is loaded by the arm 140 and from which the substrate is unloaded by the arm 140.

A plurality of substrate transfer apparatuses 100 may be provided in a limited space. Accordingly, to improve substrate throughput by the substrate transfer apparatus 100, it may be necessary to reduce the width w of the moving plate 130 that determines the footprint of the substrate transfer apparatus 100. Hereinafter, components of the substrate transfer apparatus 100 configured to minimize the width w of the moving plate 130 in consideration of movement of the arm 140 will be described in detail with reference to FIG. 1A.

The plurality of processing chambers 112 to 126 may be disposed at the periphery of the moving plate 130. Specifically, the plurality of processing chambers 112 to 126 may be disposed in the longitudinal direction at opposite edges (that is, opposite ends) of the moving plate 130. For example, the first set of processing chambers 112 to 116 may be disposed in the longitudinal direction at one edge (a left edge in FIGS. 1A and 1B) of the moving plate 130. In another example, the second set of processing chambers 122 to 126 may be disposed in the longitudinal direction at an opposite edge (a right edge in FIGS. 1A and 1B) of the moving plate 130.

The load lock chamber 160 may be disposed at one end of the moving plate 130. Specifically, as illustrated in FIG. 1A, the load lock chamber 160 may be disposed at a lower edge (that is, a lower end) of the moving plate 130. Meanwhile, although one load lock chamber 160 is illustrated in FIG. 1A, the inventive concept is not limited thereto. For example, the substrate transfer apparatus 100 may include two or more load lock chambers. In this case, a substrate to be transferred to any one processing chamber may be disposed in one load lock chamber. In addition, a substrate obtained from any one processing chamber may be disposed in another load lock chamber.

Referring to FIG. 1A, as described above, the arm 140 may transfer the substrate between the target processing chamber (here, the second processing chamber 114) among the plurality of processing chambers 112 to 126 and the load lock chamber 160. In this case, the substrate has to be loaded and unloaded at a certain position in the target processing chamber. To this end, at least a portion of the arm 140 may stop at a predetermined position on the target processing chamber when the arm 140 loads/unloads the substrate. For example, when the arm 140 loads a substrate into the sixth processing chamber 126 or unloads the substrate from the sixth processing chamber 126, at least a portion of the arm 140 may stop at a specific position 128 on the sixth processing chamber 126.

The arm 140 may include one or more joints. Accordingly, the arm 140 may include a plurality of regions 140_1 to 140_3 distinguished from one another based on the joints. For example, the arm 140 may include the first region 140_1 connected with the moving plate 130 through a joint and the third region 140_3 in which a substrate is accommodated. Additionally, the arm 140 may include the second region 140_2 disposed between the first region 140_1 and the third region 140_3 and connected, at opposite ends, with the first region 140_1 and the third region 140_3 through joints.

The joints of the arm 140 may include pivot axes, respectively. Accordingly, the plurality of regions 140_1 to 140_3 of the arm 140 may pivot around the pivot axes, respectively. For example, the first region 140_1 may pivot around a first pivot axis p1 relative to the moving plate 130. In another example, the first region 140_1 and/or the second region 140_2 may pivot around a second pivot axis p2. In another example, the second region 140_2 and/or the third region 140_3 may pivot around a third pivot axis p3.

Referring to FIGS. 1A and 1B together, the arm 140 may move along a path 150 provided by the moving plate 130. Specifically, the arm 140 may perform a circular motion in the clockwise and/or counterclockwise direction along the path 150 provided on one surface of the moving plate 130. In this case, the position of the first pivot axis p1 on the path 150 may be determined based on the target processing chamber. For example, when the target processing chamber is the second processing chamber 114 as in FIG. 1A, the first pivot axis p1 on the path 150 may be located at a right end of the path 150. In another example, when the target processing chamber is the fourth processing chamber 122 as in FIG. 1B, the first pivot axis p1 on the path 150 may be located on an upper left side (that is, on the northwest side) of the path 150. Meanwhile, although circular paths are illustrated in FIGS. 1A and 1B and FIGS. 2 to 4B, which will be described below, the inventive concept is not limited thereto. For example, an oval path may be provided. In another example, an arc-shaped path including at least a portion of a circle may be provided.

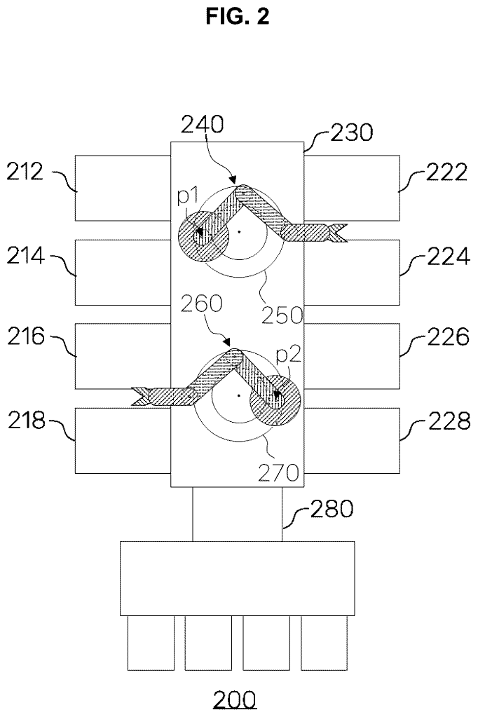

FIG. 2 is a plan view of a substrate transfer apparatus 200 including a plurality of arms and a plurality of paths according to an embodiment of the inventive concept. As illustrated, a moving plate 230 may provide a first path 250 along which a first pivot axis p1 of a first arm 240 performs a circular motion on the moving plate 230. Additionally, the moving plate 230 may provide a second path 270 along which a second pivot axis p2 of a second arm 260 performs a circular motion on the moving plate 230. In this case, the first path 250 and the second path 270 may be provided side by side on the same surface of the moving plate 230. For example, the first path 250 and the second path 270 may be disposed in the longitudinal direction on one surface of the moving plate 230.

First, an example in which both the first arm 240 and the second arm 260 directly transfer a substrate between one of a plurality of processing chambers 212 to 228 and a load lock chamber 280 will be described.

The first arm 240 may be connected with the moving plate 230 through the first path 250 and may transfer a substrate between one of the plurality of processing chambers 212 to 228 and the load lock chamber 280. Specifically, the first arm 240 may be connected with the moving plate 230 through the first path 250, may obtain the substrate from the one of the plurality of processing chambers 212 to 228, and may directly transfer the substrate to the load lock chamber 280. In this case, the second arm 260 may be connected with the moving plate 230 through the second path 270 and may transfer a substrate between another one of the plurality of processing chambers 212 to 228 and the load lock chamber 280. Specifically, the second arm 260 may be connected with the moving plate 230 through the second path 270, may obtain the substrate from the other one of the plurality of processing chambers 212 to 228, and may directly transfer the substrate to the load lock chamber 280.

The first arm 240 may be connected with the moving plate 230 through the first path 250 and may transfer a substrate between one of the first set of processing chambers 212, 214, 222, and 224 included in the plurality of processing chambers 212 to 228 and the load lock chamber 280. Here, the first set of processing chambers 212, 214, 222, and 224 may include processing chambers adjacent to the first arm 240 (or, the first path 250). Likewise, the second arm 260 may be connected with the moving plate 230 through the second path 270 and may transfer a substrate between one of the second set of processing chambers 216, 218, 226, and 228 included in the plurality of processing chambers 218 to 228 and the load lock chamber 280. Even in this case, the second set of processing chambers 216, 218, 226, and 228 may include processing chambers adjacent to the first second 260 (or, the second path 270).

Meanwhile, in contrast to the above description, the first arm 240 may transfer a substrate between one processing chamber and the load lock chamber 280 through the second arm 260. That is, the substrate transferred by the first arm 240 may be transferred to the second arm 260. Then, the second arm 260 may transfer the substrate to the load lock chamber 280. In this case, the distance between the first arm 240 (or, the first pivot axis p1) and the load lock chamber 280 may be greater than the distance between the second arm 260 (or, the second pivot axis p2) and the load lock chamber 280. Furthermore, the substrate transferred from the first arm 240 to the load lock chamber 280 via the second arm 260 may be obtained from the first set of processing chambers 212, 214, 222, and 224 adjacent to the first arm 240 among the plurality of processing chambers 212 to 228. This configuration may enable the plurality of arms 240 and 260 to transfer a substrate between a processing chamber and the load lock chamber 280 along an efficient traffic line even when the moving plate 230 is relatively long so that a large number of processing chambers are disposed in the longitudinal direction. In addition, a problem of interference (that is, collision) occurring when the plurality of arms 240 and 260 are disposed may be prevented.

Additionally, the substrate transfer apparatus 200 may further include one or more regions (not illustrated) for temporarily storing (or, accommodating) substrates during transfer of the substrates. That is, when a substrate is transferred from a first unit to a second unit of the substrate transfer apparatus 200, the substrate may reach the second unit via a predetermined region (or, after temporarily stopped). In addition, when the substrate is transferred from the first unit to the second unit of the substrate transfer apparatus 200, the substrate may reach the second unit via the predetermined region based on a state of the second unit that is a destination.

The first unit may include one of one processing chamber among the plurality of processing chambers 212 to 228, the first arm 240, the second arm 260, and the load lock chamber 280. Likewise, the second unit may include one of one processing chamber among the plurality of processing chambers 212 to 228, the first arm 240, the second arm 260, and the load lock chamber 280. However, the first unit and the second unit may be configured differently from each other because the first unit and the second unit indicate a point of departure and a destination of a substrate, respectively.

For example, the substrate transfer apparatus 200 may further include a region (hereinafter, referred to as the “first storage region”) for temporarily storing a target substrate during transfer of the target substrate between the first arm 240 and the second arm 260. To this end, the first storage region may be disposed between the first path 250 and the second path 270. Furthermore, when the second unit, which is a destination of the target substrate, is the second arm 260, the target substrate may reach the second unit via a predetermined region based on a state of the second arm 260. Accordingly, when the target substrate has to be transferred to the second arm 260 by the first arm 240 while the second arm 260 transfers another substrate, the first arm 240 may immediately place the target substrate in the first storage region and perform another task without needing to stand by until the second arm 260 completely transfers the other substrate. That is, a state of the second unit that serves as the basis for determining whether the target substrate passes through the predetermined region may be associated with at least one of movement of an arm (here, the second arm 260) that is the second unit, the position of the arm, and whether the arm accommodates another substrate.

In another example, the substrate transfer apparatus 200 may further include a region (hereinafter, referred to as the “second storage region”) for temporarily storing a substrate during transfer of the corresponding substrate between the second arm 260 and the load lock chamber 280. To this end, the second storage region may be disposed between the second path 270 and the load lock chamber 280. Accordingly, when the load lock chamber 280 is not ready to accommodate a processed target substrate, the second arm 260 may immediately place the target substrate in the second storage region and perform another task without needing to stand by until the load lock chamber 280 is ready to accommodate the target substrate. That is, a state of the second unit that serves as the basis for determining whether the target substrate passes through a predetermined region may be associated with at least one of the temperature, humidity, and pressure of a chamber (here, the load lock chamber 280) that is the second unit and whether another substrate is accommodated in the chamber.

The above-described components enable the substrate transfer apparatus 200 to more efficiently transfer a substrate. This may lead to a unique technical effect of maximizing the substrate throughput of the substrate transfer apparatus 200. Meanwhile, the regions for temporarily storing substrates may be provided in the form of a hardware module, such as a station or a chamber, on the moving plate 230.

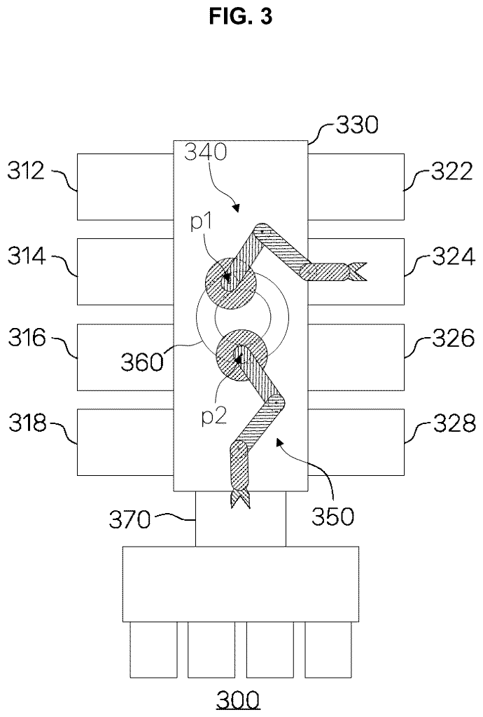

FIG. 3 is a plan view of a substrate transfer apparatus 300 including a plurality of arms according to an embodiment of the inventive concept. As illustrated, a moving plate 330 may provide a path 360 along which a first pivot axis p1 of a first arm 340 and a second pivot axis p2 of a second arm 350 perform a circular motion on the moving plate 330.

First, an example in which both the first arm 340 and the second arm 350 directly transfer a substrate between one of a plurality of processing chambers 312 to 328 and a load lock chamber 370 will be described.

The first arm 340 and the second arm 350 may be connected with the moving plate 330 through the path 360 and may transfer a substrate between one of the plurality of processing chambers 312 to 328 and the load lock chamber 370. Specifically, the first arm 340 and the second arm 350 may be connected with the moving plate 330 through the path 360, may obtain a substrate from one of the plurality of processing chambers 312 to 328, and may directly transfer the substrate to the load lock chamber 370. In this case, the first arm 340 and the second arm 350 may move in conjunction with each other along the path 360. Alternatively, the first arm 340 and the second arm 350 may move independently of each other along the path 360.

Meanwhile, in contrast to the above description, the first arm 340 may transfer a substrate between one processing chamber and the load lock chamber 370 through the second arm 350. That is, the substrate transferred by the first arm 340 may be transferred to the second arm 350. Then, the second arm 350 may transfer the substrate to the load lock chamber 370. In this case, the distance between the first arm 340 (or, the first pivot axis p1) and the load lock chamber 370 may be greater than the distance between the second arm 350 (or, the second pivot axis p2) and the load lock chamber 370. Furthermore, the substrate transferred from the first arm 340 to the load lock chamber 370 via the second arm 350 may be obtained from the first set of processing chambers 312, 312, 322, and 324 adjacent to the first arm 340 among the plurality of processing chambers 312 to 328.

Additionally, the second arm 350 may transfer a substrate between one processing chamber and the load lock chamber 370 through the first arm 340. That is, the substrate transferred by the first arm 340 may be transferred to the second arm 350. Then, the second arm 350 may transfer the substrate to the load lock chamber 370. In this case, the distance between the second arm 350 (or, the second pivot axis p2) and the load lock chamber 370 may be greater than the distance between the first arm 340 (or, the first pivot axis p1) and the load lock chamber 370. Furthermore, the substrate transferred from the second arm 350 to the load lock chamber 370 via the first arm 350 may be obtained from the first set of processing chambers 312, 314, 322, and 324 adjacent to the second arm 350 among the plurality of processing chambers 312 to 328. This configuration may enable the plurality of arms 340 and 350 to transfer a substrate between a processing chamber and the load lock chamber 370 along an efficient traffic line even when the moving plate 330 is relatively long so that a large number of processing chambers are disposed in the longitudinal direction.

Additionally, the substrate transfer apparatus 300 may further include one or more regions (not illustrated) for temporarily storing (or, accommodating) substrates during transfer of the substrates. That is, when a substrate is transferred from a first unit to a second unit of the substrate transfer apparatus 300, the substrate may reach the second unit via a predetermined region (or, after temporarily stopped).

The first unit may include one of one processing chamber among the plurality of processing chambers 312 to 328, the first arm 340, the second arm 350, and the load lock chamber 370. Likewise, the second unit may include one of one processing chamber among the plurality of processing chambers 312 to 328, the first arm 340, the second arm 350, and the load lock chamber 370. However, the first unit and the second unit may be configured differently from each other because the first unit and the second unit indicate a point of departure and a destination of a substrate, respectively. For example, the substrate transfer apparatus 300 may further include a region (hereinafter, referred to as the “first storage region”) for temporarily storing a target substrate during transfer of the target substrate between the first arm 340 and the second arm 350. To this end, the first storage region may be disposed in a region adjacent to the path 360. Furthermore, the first storage region may be disposed in a hole portion at the center of the path 360 having a ring shape. Accordingly, when the target substrate has to be transferred to the second arm 350 by the first arm 340 while the second arm 350 transfers another substrate, the first arm 340 may immediately place the target substrate in the first storage region and perform another task without needing to stand by until the second arm 350 completely transfers the other substrate. That is, a state of the second unit that serves as the basis for determining whether the target substrate passes through a predetermined region may be associated with at least one of movement of an arm (here, the second arm 350) that is the second unit, the position of the arm, and whether the arm accommodates another substrate.

In another example, the substrate transfer apparatus 300 may further include a region (hereinafter, referred to as the “second storage region”) for temporarily storing a target substrate during transfer of the target substrate between the second arm 350 and the load lock chamber 370. To this end, the second storage region may be disposed between the path 360 and the load lock chamber 370. Accordingly, when the load lock chamber 370 is not ready to accommodate the processed target substrate, the second arm 350 may immediately place the target substrate in the second storage region and perform another task without needing to stand by until the load lock chamber 370 is ready to accommodate the target substrate. That is, a state of the second unit that serves as the basis for determining whether the target substrate passes through the predetermined region may be associated with at least one of the temperature, humidity, and pressure of a chamber (here, the load lock chamber 370) that is the second unit and whether another substrate is accommodated in the chamber.

The above-described components enable the substrate transfer apparatus 300 to more efficiently transfer a substrate. This may lead to a unique technical effect of maximizing the substrate throughput of the substrate transfer apparatus 300. Meanwhile, the regions for temporarily storing substrates may be provided in the form of a hardware module, such as a station or a chamber, on the moving plate 330.

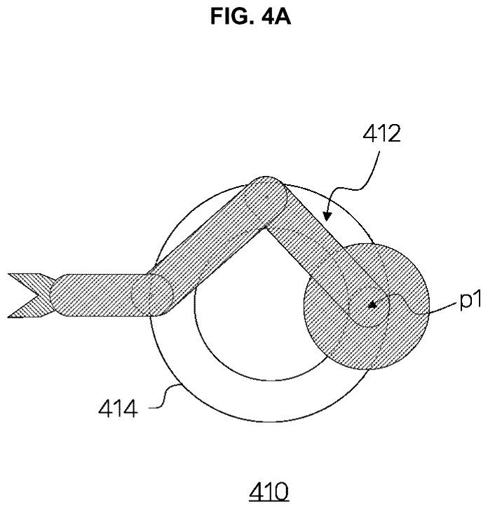

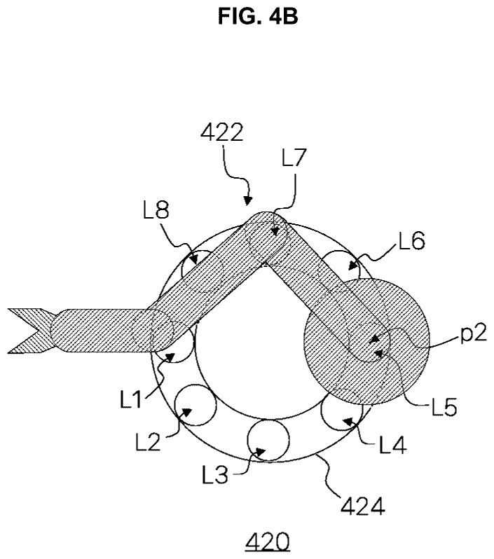

FIGS. 4A and 4B are plan views of arm units 410 and 420 including different members according to an embodiment of the inventive concept. Here, arms 412 and 422 and paths 414 and 424 of FIGS. 4A and 4B may correspond to the arms and the paths illustrated in FIGS. 1A to 3. That is, the arms illustrated in FIGS. 1A to 3 may be replaced with at least one of the arms 412 and 422 of FIGS. 4A and 4B. In addition, the paths illustrated in FIGS. 1A to 3 may be replaced with at least one of the paths 414 and 424 of FIGS. 4A and 4B.

FIG. 4A illustrates an example that the path 414 includes a rail. In this case, a first pivot axis p1 of the arm 412 may be disposed at any point along the rail included in the path 414.

In contrast, FIG. 4B illustrates an example that the path 424 includes a plurality of links L1 to L8. In this case, a second pivot axis p2 of the arm 422 may be disposed at a specific point (that is, any one link) among the plurality of links L1 to L8 included in the path 424. To this end, the path 424 of FIG. 4B may include components that allow the arm 422 to be fixed at a predetermined position while providing a travel path to the arm 422. Hereinafter, sub-components of the plurality of links L1 to L8 will be described in detail.

For example, the path 424 of FIG. 4B may include a rail and a fixing member, and the arm 422 may include a structure to which the fixing member is coupled. Specifically, the rail along which the second pivot axis p2 of the arm 422 moves may be continuously disposed along the path 424, and a plurality of fixing members may be disposed on the rail as the plurality of links L1 to L8 with a gap therebetween. Accordingly, when the second pivot axis p2 moves from a start link (e.g., the fifth link L5) to a destination link (e.g., the first link L1), a fixing member that is disposed at the start link and that fixes the position of the second pivot axis p2 may be separated from a specific structure of the arm 422. Then, the second pivot axis p2 of the arm 422 may move along the rail between the start link and the destination link and may be disposed at the destination link. Finally, a fixing member disposed at the destination link may be connected to the specific structure of the arm 422. Accordingly, the arm 422 may stably transfer a substrate without being separated from the destination link. Meanwhile, for a robust and strong coupling, the fixing members and the structure of the arm 422 may have shapes corresponding to each other (e.g., convex and concave, pin and hole, or the like).

In another example, the path 424 of FIG. 4B may include a rail and a plurality of electromagnet members, and the arm 422 may include a magnetic member (in contrast, the path 424 may include a magnetic member, and the arm 422 may include an electromagnet member). Specifically, the rail along which the second pivot axis p2 of the arm 422 moves may be continuously disposed along the path 424, and the plurality of electromagnet members may be disposed on the rail as the plurality of links L1 to L8 with a gap therebetween. Accordingly, when the second pivot axis p2 moves from the start link (e.g., the fifth link L5) to the destination link (e.g., the first link L1), an electromagnet member disposed at the start link may be demagnetized by release of current supply, and an electromagnet member disposed at the start link may be magnetized by start of current supply. In this case, electromagnet members disposed between the start link and the destination link are maintained in a demagnetized state. Then, the second pivot axis p2 of the arm 422 may move along the rail between the start link and the destination link and thereafter may be fixed to the destination link by the magnetism of the destination link. Meanwhile, for a robust and strong coupling, at least a portion of an electromagnet member that makes contact with the arm 422 may be configured in a form that corresponds to (or, is the same as) the magnetic member included in the arm 422. Accordingly, the arm 422 may be fixed at an accurate position on the destination link.

According to the embodiments of the inventive concept, substrate throughputs in limited spaces may be maximized by reducing the footprints of the substrate transfer apparatuses.

Various modifications of the inventive concept will be obvious to those skilled in the art, and the general principles defined herein may be applied to various modifications without departing from the spirit or scope of the inventive concept. Accordingly, the inventive concept is not intended to be limited to the examples set forth herein but is intended to be accorded the widest scope consistent with the principles and novel features disclosed herein.

Although example implementations may refer to utilizing aspects of the presently disclosed subject matter in the context of one or more standalone computer systems, the subject matter is not so limited, and they may be implemented in conjunction with any computing environment, such as a network or distributed computing environment. Furthermore, aspects of the presently disclosed subject matter may be implemented in or across a plurality of processing chips or devices, and storage may be similarly influenced across a plurality of devices. Such devices may include PCs, network servers, and handheld devices.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A substrate transfer apparatus comprising:
a moving plate;
a load lock chamber disposed at one end of the moving plate;
a plurality of processing chambers disposed in a longitudinal direction at opposite ends of the moving plate; and
a first arm connected with the moving plate and configured to transfer a substrate between one processing chamber among the plurality of processing chambers and the load lock chamber,
wherein the moving plate provides a first path along which a first pivot axis of the first arm performs a circular motion on the moving plate.

2. The substrate transfer apparatus of claim 1, wherein a position of the first pivot axis on the first path is determined based on a position of the one processing chamber relative to the moving plate.

3. The substrate transfer apparatus of claim 1, wherein the first path includes at least one of an oval shape and an arc shape.

4. The substrate transfer apparatus of claim 1, further comprising:
a second arm connected with the moving plate and configured to transfer the substrate between the one processing chamber among the plurality of processing chambers and the load lock chamber,
wherein the moving plate provides the first path along which each of the first pivot axis of the first arm and a second pivot axis of the second arm performs a circular motion on the moving plate.

5. The substrate transfer apparatus of claim 4, wherein the substrate is configured to pass through the second arm between the one processing chamber and the load lock chamber.

6. The substrate transfer apparatus of claim 1, further comprising:
a third arm connected with the moving plate and configured to transfer the substrate between the one processing chamber among the plurality of processing chambers and the load lock chamber,
wherein the moving plate provides a second path along which a third pivot axis of the third arm performs a circular motion on the moving plate.

7. The substrate transfer apparatus of claim 1, wherein the first path includes a rail.

8. The substrate transfer apparatus of claim 1, wherein the first path includes a plurality of links, and the first pivot axis is disposed at one of the plurality of links to transfer the substrate from the one processing chamber.

9. The substrate transfer apparatus of claim 1, wherein when the substrate is transferred from a first unit to a second unit, the substrate reaches the second unit via a predetermined region based on a state of the second unit, and
wherein each of the first unit and the second unit includes one of the load lock chamber, the one processing chamber, and the first arm, and the first unit and the second unit are configured differently from each other.

10. The substrate transfer apparatus of claim 9, wherein when the second unit is the first arm, the state is associated with at least one of movement of the first arm, a position of the first arm, and whether the first arm accommodates another substrate.

11. The substrate transfer apparatus of claim 9, wherein when the second unit is the load lock chamber or the one processing chamber, the state is associated with at least one of temperature, humidity, and pressure of the load lock chamber or the one processing chamber and whether another substrate is accommodated in the load lock chamber or the one processing chamber.
